(19) United States
(12) Patent Application Publication
(10) Pub. No.: US 2009/0301557 A1
(43) Pub. Date: Dec. 10, 2009

(54) METHOD FOR PRODUCING PHOTOVOLTAIC CELLS AND PHOTOVOLTAIC CELLS OBTAINED BY SUCH METHOD

(75) Inventors: Guido Agostinelli, Bruxelles (BE); Guy Beaucarne, Oud-Heverlee (BE); Patrick Choulat, Leuven (BE)

Correspondence Address: KNOBBE MARTENS OLSON & BEAR LLP, 2040 MAIN STREET, FOURTEENTH FLOOR, IRVINE, CA, 92614, US

(73) Assignee: Interuniversitair Microelektronica Centrum (IMEC) vzw, Leuven (BE)

(21) Appl. No.: 11/855,988

(22) Filed: Sep. 14, 2007

Related U.S. Application Data
(63) Continuation of application No. PCT/EP2006/002409, filed on Mar. 16, 2006.
(60) Provisional application No. 60/662,613, filed on Mar. 16, 2005.

(30) Foreign Application Priority Data
Sep. 9, 2005 (EP) EP 05447200.6

(51) Int. Cl. H01L 31/0216; H01L 31/02

(52) U.S. Cl. 136/256; 438/98; 257/E31.119

(57) ABSTRACT

A method for the production of a photovoltaic device, for instance a solar cell, is disclosed. In one aspect, the method comprises providing a substrate having a front main surface and a rear surface. The method further comprises depositing a dielectric layer on the rear surface, wherein the dielectric layer has a thickness larger than about 100 nm. The method further comprises depositing a passivation layer comprising hydrogenated SiN on top of the dielectric layer and forming back contacts through the dielectric layer and the passivation layer. In another aspect, corresponding photovoltaic devices, for instance solar cell devices, are also disclosed.

### CROSS REFERENCE TO RELATED APPLICATIONS

This application is a continuation of International Application PCT/EP2006/002409, filed on Mar. 16, 2006, which claims priority under 35 U.S.C. § 119(e) to U.S. provisional patent application 60/662,613 filed on Mar. 16, 2005. Each of the above applications is incorporated by reference hereby in its entirety.

### BACKGROUND OF THE INVENTION

1. Field of the Invention

The present invention relates to the field of photovoltaic cells. More particularly it relates to a method of manufacturing photovoltaic cells and to photovoltaic cells thus obtained.

2. Description of the Related Technology

Significant cost reduction of bulk crystalline silicon solar cells requires the removal of the technological barriers that impede the development of a high throughput, low cost, and reliable industrial process on thin substrates. Present industrial surface conditioning and rear surface passivation processes do not meet the requirements for yield and performance on thin substrates. A well-established process step such as the full area, screen printed Al-Alloyed BSF (Back Surface Field) is to be abandoned, due to insufficient performance and excessive warping of the wafers below about 200 μm. There exist a variety of solutions for laboratory scale production, but these are not applicable to commercial quality material, nor would guarantee cost effectiveness and throughput.

The major problem is that of passivating the rear surface and, at the same time, providing (local) electrical contacts of an ohmic nature and a limited surface recombination velocity to the base.

Engineering a dielectric with surface passivation properties that are resistant to contact firing with a process that is not harmful to the bulk lifetime of commercial quality materials (e.g. mono-crystalline or Cz-Si, multi-crystalline or mc-Si), and that does not interact with the rear side metallization is all but a trivial task. Most dielectrics lose their passivation properties during the rapid thermal treatment, which is necessary to fire the front contacts through the ARC, and it is known that interaction between the rear side aluminum and the dielectric can jeopardize the cell efficiency, despite excellent results of surface passivation on bifacial samples reported in literature for a variety of dielectric layers on silicon. Nor is it trivial to integrate such layer in a complete solar cell process sequence, given the repeated high temperature treatments and cleaning/etching steps that need to be carried out in a given sequence.

In “Effective passivation of the low resistivity silicon surface by a rapid thermal oxide/plasma silicon nitride stack”, Applied Physics Letters, Volume 72, Number 15, 13 Apr. 1998, a passivation process is described for a low resistivity silicon surface. A rapid thermal oxide (RTO) is deposited by rapid thermal processing (RTP) at 900° for 5 minutes, followed by the deposition of a SiN layer by Plasma Enhanced Chemical Vapor Deposition process (PECVD). An effect is shown of the RTO temperature on the passivation of the stack. The RTO layer is about 7.9 nm thick. No photovoltaic cell production process is performed. No solar cell rear surface passivation process is performed nor analyzed.

In “The effect of Low and High Temperature Anneals on the Hydrogen Content and Passivation of Si Surface with SiO₂ and SiN Films”, Journal of The Electrochemical Society, 146 (5) 1921-1924 (1999) different Si surface passivation schemes are investigated and compared. It is suggested that the release of hydrogen from SiN during the anneal further passivates the RTO/Si interface underneath. The examples comprise thin oxide layers of about 10 nm. For low quality oxides a lower passivation property is indicated. No solar cell production process is performed nor analyzed.

In “Investigation of various surface passivation layers using oxide/nitride stacks of silicon solar cells”, Lee, J. Y.; Dicker, J.; Rein, S.; Glunz, S. W.; Proceedings of 3rd World Conference on Photovoltaic Energy Conversion, Osaka 2003, 12-16 May 2003, p 1069-p 1072 Vol. 2, different surface passivation processes based on Classical Thermal Oxidation (CTO), RTO, SiNx and oxide/nitride stacks are tested and introduced in solar cells. It is concluded a) that oxide/nitride stack passivation relies on a combined native low density of interface states at the SiO₂/Si interface and high fixed charge density at the SiNx/SiO₂ interface and b) that nevertheless oxide/nitride stacks have a weak front and rear surface passivation when introduced in solar cells. Point a) suggests that for passivation to be effective,
the oxide/silicon interface shall be natively of a good quality, and
the oxide shall be as thin as possible, because the thinner the oxide, the stronger the field effect passivation due to the nitride charges.

### SUMMARY OF CERTAIN INVENTIVE ASPECTS

Certain inventive aspects provide photovoltaic cells and a method for producing a photovoltaic cell, which alleviates or avoids some problems of the prior art and reduces the production cost.

In a first embodiment of a first aspect of the present invention a method for the production of a photovoltaic device as for instance a solar cell is disclosed, comprising:
i. providing a semiconductor substrate, e.g. a silicon substrate, having a front main surface for collecting impinging light, e.g. sunlight, and a rear surface opposite to the front main surface,
ii. depositing a dielectric layer or a wide bandgap semiconductor layer on the rear surface, wherein the dielectric layer or wide bandgap semiconductor layer has a thickness larger than about 100 nm, preferably larger than about 120 nm, still more preferred larger than about 150 nm or larger than about 200 nm,
iii. depositing a passivation layer comprising hydrogenated SiN on top of the dielectric layer or wide bandgap semiconductor layer, and
iv. forming back contacts through the dielectric layer or wide bandgap semiconductor layer and the passivation layer.

In another embodiment of the first aspect of the present invention a method for the production of a photovoltaic device as for instance a solar cell is disclosed, comprising:
i. providing a semiconductor substrate, e.g. a silicon substrate, having a front main surface for collecting impinging light, e.g. sunlight, and a rear surface opposite to the front main surface,
ii. depositing a SiN layer or a SiN:H layer on the rear surface, wherein the SiN layer or SiN:H layer has a thickness larger than about 100 nm, preferably larger than about 120 nm, still more preferred larger than about 150 nm, larger than about 180 nm or larger than about 200 nm,
iii. forming back contacts through the SiN layer or SiN:H layer.

In case of bifacial solar cells, both the front main surface and the rear surface are adapted to receive impinging light. In that case, the front main surface is that surface adapted for receiving the largest fraction of the impinging light.

The layer of hydrogenated SiN functions as a passivating layer in that it releases hydrogen (during a subsequent high-temperature process) and induces the charges that allow for a good surface passivation of the dielectric/substrate interface.

Depositing a dielectric layer or a wide bandgap semiconductor layer on the rear surface may comprise depositing a low quality dielectric layer. Depositing a dielectric layer on the rear surface may comprise depositing a SiN layer, or a hydrogenated SiN layer. Alternatively, depositing a dielectric layer on the rear surface may comprise depositing a low quality oxide. The low quality oxide may comprise low quality amorphous oxide, e.g. amorphous silicon oxide, which can reduce production costs when compared to production of high quality oxide. The low-quality amorphous oxide may be any of APCVD pyrolithic oxide, spin-on oxide, spray-on oxide or dip oxide. In embodiments of the present invention, the dielectric layer may be a deposited dielectric layer. Deposited dielectric layers are typically of lower quality than grown dielectric layers.

In embodiments of the present invention, the production rate (which can be growth rate or deposition rate) of the dielectric layer or wide bandgap semiconductor layer, expressed in layer thickness per minute (min), may be higher than about 5 nm per min, or higher than about 10 nm per min, or higher than about 20 nm per min, or higher than about 30 nm per min, or higher than about 50 nm per min.

A grown silicon dioxide is formed as the product of a reaction between the Si of the substrate and oxygen provided through the gas phase. In the case of a deposited oxide or dielectric none of the reagents comes from the substrate or the silicon layer. A low-quality dielectric layer, e.g. amorphous oxide, can for instance be a Spin-on oxide or APCVD (Atmospheric pressure chemical vapor deposition) pyrolithic oxide (pyrox), spin-on, spray-on or dip oxide. It can be for instance a silicon oxide, TiO2 (e.g. deposited by solgel), or Al2O3/TiO2 pseudobinary alloys (PBAs).

Depositing the dielectric layer or wide bandgap semiconductor layer at certain temperatures may bring certain advantageous effects, some of which are described below. In embodiments of the present invention, the deposition temperature may be lower than about 600° C., hereby allowing processing without thermal poisoning of substrates. In embodiments of the present invention, the dielectric may be deposited e.g. by PECVD at a temperature below about 500° C. In embodiments of the present invention, the deposition temperature may be lower than about 410° C., which can be achieved by using for instance pyrox (having a typical deposition temperature of about 404° C.). In embodiments of the present invention the dielectric or wide bandgap semiconductor layer may be deposited by low temperature PEVCD (<about 300° C.). In other embodiments of the present invention, the deposition may be done at Room Temperature e.g. by spin-on, spray-on, dip or any other deposition from liquid, sol, solgel. The resulting dielectric layer or wide bandgap semiconductor layer may need further curing at higher temperatures, which can happen during further cell processing.

In a second embodiment of the first aspect of the present invention, a method for the production of a photovoltaic device as for instance a solar cell is disclosed, comprising:
i. providing a semiconductor substrate, e.g. a silicon substrate, having a front main surface for collecting impinging light, e.g. sunlight, and a rear surface opposite to the front main surface,
ii. depositing a dielectric layer stack on the rear surface, wherein the dielectric layer stack comprises a sub-stack of dielectric layers and/or wide bandgap semiconductor layers, the sub-stack having a thickness larger than about 100 nm, preferably larger than about 150 nm, preferably larger than about 200 nm, the dielectric layer stack having a thickness larger than about 200 nm, preferably larger than about 250 nm, preferably larger than about 300 nm, and
iii. forming back contacts through the dielectric layer stack.

Depositing a dielectric layer stack on the rear surface may comprise depositing the sub-stack of dielectric layers and/or wide bandgap semiconductor layers on the rear surface, and depositing a passivation layer on top of the sub-stack. In that case, the thickness of the passivation layer is not included in the thickness of the stack. The passivation layer can have any suitable thickness. The passivation layer may be a SiN layer, preferably a hydrogenated SiN layer.

Depositing a sub-stack of dielectric layers and/or wide bandgap semiconductor layers on the rear surface may comprise depositing a low quality dielectric layer, such as a low quality oxide. The low quality oxide may comprise low quality amorphous oxide, e.g. amorphous silicon oxide, which can reduce production costs when compared to production of high quality oxide. The low-quality amorphous oxide may be any of APCVD pyrolithic oxide, spin-on oxide, spray-on oxide or dip oxide. In embodiments of the present invention, the dielectric layer may be a deposited dielectric layer. Deposited dielectric layers are typically of lower quality than grown dielectric layers.

In embodiments of the present invention, the production rate (which can be growth rate or deposition rate) of the dielectric layers and/or wide bandgap semiconductor layers, expressed in layer thickness per minute (min), may be higher than about 5 nm per min, or higher than about 10 nm per min, or higher than about 20 nm per min, or higher than about 30 nm per min, or higher than about 50 nm per min.

A grown silicon dioxide is formed as the product of a reaction between the Si of the substrate and oxygen provided through the gas phase. In the case of a deposited oxide or dielectric none of the reagents comes from the substrate or the silicon layer. A low-quality dielectric layer, e.g. amorphous oxide, can for instance be a Spin-on oxide or APCVD (Atmospheric pressure chemical vapour deposition) pyrolithic oxide (pyrox), spin-on, spray-on or dip oxide. It can be for instance a silicon oxide, TiO2 (e.g. deposited by solgel), or Al2O3/TiO2 pseudobinary alloys (PBAs).

Depositing the sub-stack of dielectric layers and/or wide bandgap semiconductor layers at certain temperatures may bring certain advantageous effects, some of which are described below. In embodiments of the present invention, the deposition temperature may be lower than 600° C., hereby allowing processing without thermal poisoning of substrates. In embodiments of the present invention, the sub-stack of dielectric layers and/or wide bandgap semiconductor layers may be deposited e.g. by PECVD at a temperature below about 500° C. In embodiments of the present invention, the deposition temperature may be lower than about 410° C., which can be achieved by using for instance pyrox (having a typical deposition temperature of about 404° C.). In embodiments of the present invention the sub-stack of dielectric layers and/or wide bandgap semiconductor layers may be deposited by low temperature PEVCD (<about 300° C.). In other embodiments of the present invention, the deposition may be done at room temperature e.g. by spin-on, spray-on, dip or any other deposition from liquid, sol, solgel. The resulting sub-stack of dielectric layers and/or wide bandgap semiconductor layers may need further curing at higher temperatures, which can happen during further cell processing.

In any of the embodiments of the first aspect of the present invention, if a silicon substrate is used, any kind of silicon substrate may be used. Some Examples of silicon substrates are Czochralski Si (cz-Si) wafers, Float-Zone Si (fz-Si) wafers, multicrystalline Si (mc-Si) wafers and Ribbon Si wafers. Some examples of layers are polycrystalline silicon layers which can be put on glass or glass-ceramic, or monocrystalline Si layers obtained by a lift-off process

In any of the embodiments of the first aspect of the present invention, the thickness of the dielectric layer or wide bandgap semiconductor layer or sub-stack of dielectric layers and/or wide bandgap semiconductor layers may be between about 100 nm and 5000 nm, preferably between about 100 nm and 4000 nm, more preferred between about 100 nm and 3000 nm, still more preferred between about 100 nm and 2000 nm, still more preferred between about 100 nm and 1500 nm, still more preferred between about 150 nm and 1200 nm, more preferably between about 200 nm and 1200 nm, still more preferably between about 600 nm and 1200 nm or between about 800 nm and 1200 nm. Alternatively, the thickness of the dielectric layer or wide bandgap semiconductor layer or dielectric layer stack may be between about 400 nm and 800 nm. In embodiments of the present invention, the minimal thickness of the dielectric layer or wide bandgap semiconductor layer or dielectric layer stack depends on the material which is employed and is determined by the amount of material which is necessary to act simultaneously as a diffusion mask during emitter diffusion, while still being of use for surface passivation and contact formation. For pyrox Silicon Oxide this is typically about 300 mm, for Al2O3/TiO2 pseudobinary alloys (PBAs) deposited by solgel this is about 150 mm. Those thickness values are only indicative and a deviation of about 10%, 20% or more from the given values is possible. Also a combination, or a stack of layers, of different materials are possible and would lead to a pre-determined threshold thickness for the combined diffusion mask, surface passivation and contact formation process.

It is a function of the dielectric layers or wide bandgap semiconductor layers applied at the rear surface of a photovoltaic device, for instance a solar cell to increase the distance between the back contact material and the substrate surface. It has been found, surprisingly, that, for a distance between about 100 nm and 5000 nm, the larger the distance between the contacting layer at the rear surface of the photovoltaic device, for instance solar cell, and the rear surface of the substrate, the better the achieved passivation results, even with low quality dielectric materials or wide bandgap semiconductor layers being applied. It is an advantage of embodiments of the present invention that sufficient passivation results may be achieved while using low-quality dielectrics. Deposition of such low-quality dielectric layers may be performed by low-cost deposition techniques which may be fast.

In a method according to embodiments of the first aspect of the present invention, forming back contacts may comprise forming holes in the dielectric layer or wide bandgap semiconductor layer and the passivation layer or in the dielectric layer stack possibly provided with a passivation layer, and depositing a layer of contacting material onto the passivation layer or onto the dielectric layer stack, hereby filing the holes.

Forming holes may be performed by applying an etching paste, by mechanical scribing or by laser ablation.

In a method according to embodiments of the present invention, depositing a layer of contacting material may be performed by evaporation, sputtering or screen printing, inkjet printing, stencil printing. Metals can be used as contacting materials, although advantageously Aluminum can be used. The method offers advantages when using Aluminum paste, allowing the formation of local BSF (Back Surface Field) contacts. Alternatively, after depositing the passivation layer and firing it, one could deposit, instead of a metal, a p+ (or n+ on n-type substrates) semiconductor (like a-Si) by e.g. PECVD and then deposit a metal on top of it.

In a method according to embodiments of the present invention, the layer of contacting material may be discontinuous. During the process of depositing the layer of contacting material, the contacting material may be deposited essentially in the holes. Different ways of depositing such a discontinuous layer of contact material exist, and are known by a person of ordinary skill.

In embodiments of the present invention, the layer of contacting material may be initially discontinuous. This means that different areas can be covered with contacting material, whereby those different areas are not electrically connected to each other. These areas can be electrically connected later on in order to allow an optimal current flow through the device and/or an external load.

In embodiments of the present invention, the layer of contacting material may be deposited in such way that light can also enter the device from the rear side, thereby allowing the production of bifacial solar cells.

In embodiments of the present invention, a high temperature process may be applied to the layer of contacting material, i.e. a process at a temperature between about 600 and 1000 degrees Celsius, such as for example firing of the front and rear contacts in a rapid thermal process (tens of seconds). In general the method described herein may be used with or without the high temperature process, but a distinctive feature over the prior art is that the dielectric layer or wide bandgap semiconductor layer or dielectric layer stack is resistant to such high temperature process, which is necessary in all industrial solar cells. In addition, during the high temperature process, for instance in a particular embodiment when using a SiNx:H/dielectric stack, the surface passivation of the dielectric/silicon interface is improved. This high temperature process may e.g. be a contact firing process which may be performed at a temperature higher than about 730 degrees Celsius and below about 960 degrees Celsius, for maximum about a few tens of seconds. The firing process can be “co-firing” when the front and rear side contact are created at the same time. When this is decoupled, the rear side can be fired above 800 degrees Celsius, and subsequently the front contact can be fired around 750 degrees Celsius (and possibly followed by a forming gas anneal—FGA—) The numbers in the last paragraph are indicative and certain variations are possible (e.g. of about 25%).

In alternative embodiments of the first aspect of the present invention, forming back contacts may be performed by applying a continuous layer of contacting material, e.g. metal, and applying local firing of the layer of contacting material, i.e. local heating e.g. by a laser. In this case, the continuous layer of contacting material can also serve as a back mirror.

In still alternative embodiments of the first aspect of the present invention, forming back contacts may be performed by applying a patterned metal layer at the passivated rear surface of the photovoltaic device, for instance solar cell, and applying a general heating process.

A method according to embodiments of the present invention may further comprise a process of diffusion and emitter removal on the surface to be passivated (i.e. rear surface) before depositing the dielectric layer or wide bandgap semiconductor layer or the dielectric layer stack. However, if the dielectric layer or wide bandgap semiconductor layer or the dielectric layer stack is suitable for being used as a diffusion mask, these layers may be applied before the formation of the emitter takes place. In this case, no dopants will enter into the substrate at the rear surface of the device, and thus it is advantageous that according to embodiments of the present invention emitter removal on the surface to be passivated may be avoided.

In a method according to embodiments of the present invention, for instance according to the first embodiment of the first aspect of the present invention, a process of diffusion may be applied after the process of depositing a dielectric layer or wide bandgap semiconductor layer and before the process of depositing a passivation layer.

In the same embodiment, the dielectric layer or wide bandgap semiconductor layer may be used as a diffusion mask. In advantageous embodiments of the present invention, the dielectric layer or wide bandgap semiconductor layer can be used simultaneously as a diffusion mask and for the purpose of surface passivation, thereby simplifying the cell process sequence. The dielectric layer or a wide bandgap semiconductor layer can be used as a diffusion mask, whether it is patterned or not. Normally it will not be patterned, and it is just a mask on the full rear surface. It may, however, be patterned e.g. for interdigitated or back contacted solar cells. Later on, the dielectric layer or wide bandgap semiconductor layer, whether patterned or not, may be locally removed, ablated, etched or patterned in order to create openings for local contacts to the substrate surface.

In embodiments of the present invention, when it is not possible to use the passivation layer as a diffusion mask, a further process can be comprised of diffusion with another mask to be etched off, or maskless diffusion with subsequent rear side parasitic emitter removal before depositing the dielectric layer or wide bandgap semiconductor layer.

In a method according to embodiments of the present invention, the front main surface may have undergone a typical solar cell front surface processing. A typical solar cell front surface process may comprise texturing of the front surface, diffusion of phosphorus atoms at the front side, etching of the phosphorus glass and the deposition of a silicon nitride layer on the front side. Alternatively, the method as recited hereinabove for the rear surface may also be applied to the front main surface of the solar cell.

In a method according to embodiments of the present invention, the substrate, e.g. silicon substrate, may be an ultra-thin substrate, which is typically thinner than about 250 micron, preferably thinner than about 200 micron, or more preferred thinner than about 150 micron. Reducing the thickness of the substrate allows a more efficient use of prime material, hence a lower cost. However, ultra-thin substrates may bow under or after certain treatments, and embodiments of the present invention improve the resistance against bowing of such ultra-thin substrates, therefore reducing at least some of the difficulties of the use of ultra-thin substrates for photovoltaic device, for instance solar cell, fabrication.

In a particular embodiment, the first aspect of the present invention provides a method for the production of a photovoltaic device, for instance solar cell, comprising:
1. providing a silicon substrate or silicon layer or a silicon thin film having a front main surface and a rear surface,
2. depositing a dielectric layer on the rear surface, for example, the dielectric layer having a thickness larger than about 100 nm, e.g. between about 200 nm and 1200 nm,
3. depositing a passivation layer comprising hydrogenated SiN on top of the dielectric layer,
4. forming holes in the dielectric layer and the SiN:H layer,
5. depositing a layer of contacting material onto the dielectric layer, hereby filling the holes, and
6. applying a high temperature process, i.e. applying a temperature between about 600 and 1000 degrees Celsius to the contacting material.

Features of other embodiments of the present invention as recited hereinabove can be combined with this particular embodiment as applicable, and not merely as set out in the present description.

In a second aspect of the present invention a photovoltaic device as for instance a solar cell device is disclosed, corresponding to the methods of the first aspect of the invention. Other photovoltaic devices are possible, as for instance radiation detectors. It should be understood that motivations, variations, alternative embodiments, limitations, etc. which are explained in the context of the method, also apply to the device.

In a first embodiment of the second aspect, a photovoltaic device as for instance a solar cell device is disclosed comprising
1. a semiconductor substrate, e.g. silicon substrate, or layer, e.g. silicon layer, or thin film, e.g. silicon thin film, having a front main surface for collecting impinging light, e.g. sunlight, and a rear surface opposite to the front main surface,
2. a dielectric layer or a wide bandgap semiconductor layer on the rear surface, the dielectric layer or wide bandgap semiconductor layer having a thickness larger than about 100 nm, preferably larger than about 150 nm,
3. a passivation layer comprising hydrogenated SiN on top of the dielectric layer or wide bandgap semiconductor layer, and
4. back contacts through the dielectric layer or wide bandgap semiconductor layer and the passivation layer.

If a silicon substrate is used, any kind of silicon substrate may be used. Some examples of silicon substrates are Czochralski Si (cz-Si) wafers, Float-Zone (fz-Si) Si wafers, multicrystalline Si (mc-Si) wafers and Ribbon Si wafers. Some examples of layers are polycrystalline silicon layers, which can be put on glass or glass-ceramic, or mono crystalline Silicon layers obtained by a lift-off process.

In the first embodiment of the second aspect of the present invention, the dielectric layer or wide bandgap semiconductor layer on the rear surface may consist of a SiN layer with a thickness larger than about 100 nm, preferably with a thickness larger than about 200 nm. In a preferred embodiment, the deposited SiN layer is a hydrogenated SiN layer.

In a second embodiment of the second aspect, a photovoltaic device as for instance a solar cell device is disclosed comprising
1. a semiconductor substrate, e.g. silicon substrate, or layer, e.g. silicon layer, or thin film, e.g. silicon thin film, having a front main surface for collecting impinging light, e.g. sunlight, and a rear surface opposite to the front main surface,
2. a dielectric layer stack on the rear surface, wherein the dielectric layer stack comprises a sub-stack of dielectric layers and/or wide bandgap semiconductor layers, the sub-stack having a thickness larger than about 100 nm, preferably larger than about 150 nm, and the dielectric layer stack having a thickness larger than about 200 nm, preferably larger than about 250 nm, and
3. back contacts through the dielectric layer stack.

The dielectric layer stack may comprise a passivation layer on top of the sub-stack of dielectric layers and/or wide bandgap semiconductor layers, e.g. a SiN layer. In this case, the passivation layer does not form part of the stack with a thickness larger than about 200 nm.

In a photovoltaic device according to embodiments of the present invention, a high quality layer, e.g. an aluminum oxide layer, may be present between the rear surface of the substrate and the sub-stack of dielectric layers and/or wide bandgap semiconductor layers.

In embodiments of the second aspect of the present invention, the thickness of the dielectric layer or a wide bandgap semiconductor layer or sub-stack of dielectric layers and/or wide bandgap semiconductor layers may be approximately between 100 nm and 5000 nm, preferably between 100 nm and 4000 nm, more preferred between 100 nm and 3000 nm, still more preferred between 100 nm and 2000 nm, still more preferred between 100 nm and 1500 nm, still more preferred between 150 nm and 1200 nm, more preferably between 200 nm and 1200 nm, still more preferably between 600 nm and 1200 nm or between 800 nm and 1200 nm. Alternatively, the thickness of the dielectric layer or wide bandgap semiconductor layer or dielectric layer stack may be approximately between 400 nm and 800 nm. In embodiments of the present invention, the minimal thickness of the dielectric layer or wide bandgap semiconductor layer or dielectric layer stack depends on the material which is employed and is determined by the amount of material which is necessary to act simultaneously as a diffusion mask during emitter diffusion, while still being of use for surface passivation and contact formation. For pyrox SiOx this is typically about 300 nm, for Al2O3/TiO2 pseudobinary alloys (PBAs) deposited by solgel this is about 150 nm. Those thickness values are only indicative and a deviation of 10%, 20% or more from the given values is possible. Also a combination, or a stack of layers, of different materials are possible and would lead to a pre-determined threshold thickness for the combined diffusion mask, surface passivation and contact formation process.

In embodiments of the second aspect of the present invention, the dielectric layer or a wide bandgap semiconductor layer or sub-stack of dielectric layers and/or wide bandgap semiconductor layers may comprise a low quality dielectric layer. The low quality dielectric layer may comprise a low quality oxide, such as low quality amorphous oxide, e.g. amorphous silicon oxide, which can reduce production costs when compared to production of high quality oxide. In embodiments of the present invention, the dielectric layer may be a deposited dielectric layer. Deposited dielectric layers are typically of lower quality than grown dielectric layers.

The low-quality dielectric, e.g. amorphous oxide, can for instance be a Spin-on oxide or APCVD (Atmospheric pressure) pyrolithic oxide, spin-on, spray-on or dip oxide . . . . It can be for instance a silicon oxide, TiO2 (e.g. deposited by solgel), or Al2O3/TiO2 pseudobinary alloys (PBAs).

A low-quality amorphous oxide presents several advantages with respect to high quality, grown oxides, in that it can e.g. be cheaper and less harmful to the lifetime of the bulk material.

In embodiments of the present invention, the back contacts may be formed by holes in the dielectric layer or wide bandgap semiconductor layer and the passivation layer or in the dielectric layer stack, possibly also provided with a passivation layer, which holes are filled with electrically conductive contact material.

In embodiments of the present invention, the layer of contacting material may be discontinuous. This means that different areas can be covered with contacting material, whereby those different areas are not connected to each other. In an advantageous example of a discontinuous layer of contacting material, the contacting material can be present essentially in the holes.

In alternative embodiments of the present invention, the back contacts may be formed by applying a continuous layer of contacting material, e.g. metal, and applying local firing of the layer of contacting material, i.e. local heating e.g. by a laser. In this case, the continuous layer of contacting material can also serve as a back mirror.

In still alternative embodiments of the present invention, back contacts may be formed by applying a patterned metal layer at the passivated rear surface of the photovoltaic device, for instance solar cell, and applying a general heating process.

In embodiments of the present invention, the device may be bifacial.

In embodiments of the present invention, the front main surface may comprise a typical solar cell front surface. Alternatively, the front main surface may comprise a structure as described hereinabove.

In certain advantageous embodiments the substrate has a thickness approximately smaller than 250 micron or smaller than 200 or 150 micron. Reducing the thickness of the substrate allows a more efficient use of prime material, hence a lower cost.

It has been shown that working solar cells with a substrate thickness down to about 90 μm thickness can be produced (efficiencies of 11% have been easily achieved) with certain embodiments without showing any bowing problem despite the use of screen printed Al paste for contacting on the full rear side.

In a particular embodiment, the second aspect of the present invention provides a photovoltaic device as for instance a solar cell device, comprising
1. a silicon substrate or silicon layer or silicon thin film having a front main surface and a rear surface,
2. a dielectric layer on the rear surface, the dielectric layer having a thickness approximately larger than 100 nm, e.g. between about 200 nm and 1200 nm,
3. a passivation layer comprising hydrogenated SiN on top of the dielectric layer,
4. holes through the dielectric layer and the SiN:H layer, and
5. a layer of contacting material onto the dielectric layer, the layer also filling the holes.

It should be noted that some layers formed or produced, grown or deposited by a certain technique can successfully afterwards be investigated to retrieve their formation technique. An example of such a technique is for instance the inspection of TEM (Tunneling electron microscopy) pictures, but other techniques can be used, which are known to a person skilled in the art.

The method can be applied in the field of back contacted solar cells. This would result in a back contacted solar cell, which can further comprise features of the devices

Particular and preferred aspects of the invention are set out in the accompanying independent and dependent claims. Features from the dependent claims may be combined with features of the independent claims and with features of other dependent claims as appropriate and not merely as explicitly set out in the claims.

### BRIEF DESCRIPTION OF THE DRAWINGS

FIG. 1 illustrates an example of a photovoltaic device, as e.g. a solar cell, and the fabrication process according to an embodiment of the present invention.

FIG. 2 illustrates embodiments of the photovoltaic device and the fabrication process.

FIG. 3 shows exemplary effective lifetime of a group of bifacial Cz silicon wafers after different passivation and thermal treatments. The samples are measured at an injection level of 10¹⁴ excess carriers/cm³. It is shown that deposition and firing of hydrogenated SiNx are beneficial to the layer on both as deposited and thermally treated/diffused (cycle in POCl₃ diffusion furnace) samples.

FIG. 4 shows examples of the open circuit voltage of the cell. In FIG. 4, a figure of merit parameter that correlates directly to the quality of the rear side passivation layer, is shown as a function of the thickness of the deposited low quality dielectric.

FIG. 5 illustrates the open circuit voltage of three cells with different rear surface passivation schemes.

### DETAILED DESCRIPTION OF CERTAIN INVENTIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

The present invention will be explained with respect to silicon substrates, but the invention is not limited thereto. Other suitable substrates can be used as well.

In a first embodiment of the present invention, a thick SiN layer is deposited on a silicon substrate. The SiN layer has a thickness larger than about 100 nm, preferably a thickness of at least about 180 nm. When formed into a solar cell, such structure shows increased cell efficiencies for higher dielectric thicknesses. Furthermore, the cell efficiencies for dielectric layers thicker than about 100 nm have been found to be better than prior art cell efficiencies with lower dielectric thicknesses.

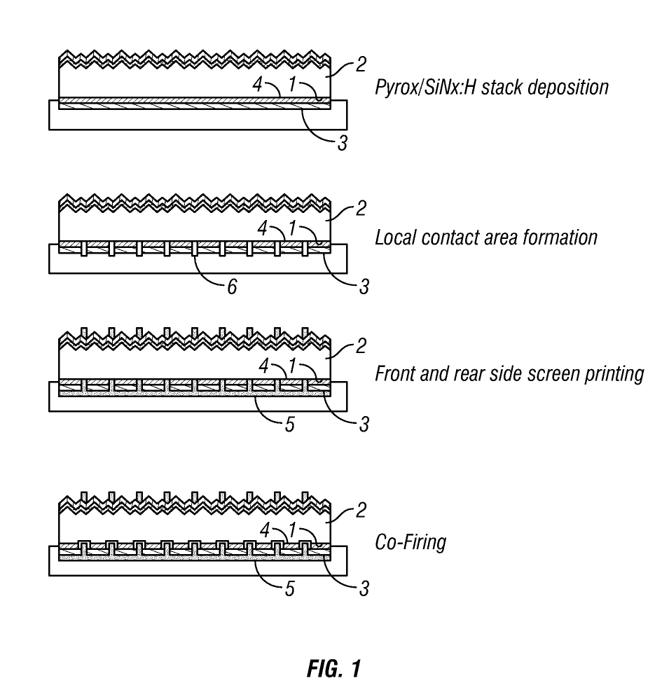

In a second embodiment of the present invention, as illustrated in FIG. 1, for instance more than about 100 nm, 200 nm, 800 nm of dielectric 1, e.g. oxide, are deposited on the substrate surface 4, e.g. silicon surface. On top of the dielectric 1, a layer of SiNx:H 3 optimized for hydrogen release is deposited. The substrate surface passivation is improved by hydrogenation.

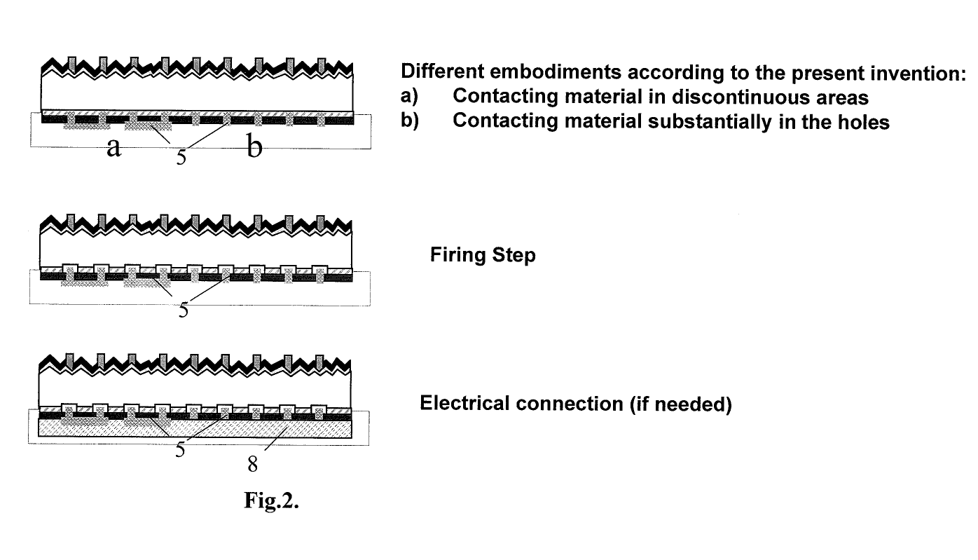

The dielectric layer stack 1, 3 thus formed is then opened up by forming holes 6 in the stack, to form local contact areas. A layer of contacting material 5 is applied onto the dielectric layer stack 1, 3, hereby filling the holes. This may be done by screen printing, for example by simultaneously or consecutively front and rear side screen printing. A high temperature process such as cofiring is then applied in order to make contact with the substrate 2. The contacting material 5 may be applied as a continuous layer, or as a discontinuous layer as in FIG. 2. This means that different areas can be covered with contacting material 5, whereby those different areas are not electrically connected to each other. These areas can be electrically connected later on by electrical connection layer 8 in order to allow an optimal current flow through the device and/or an external load.

A rear side passivation layer has thus been developed that (a) retains or improves its surface passivation qualities during the firing process, that (b) cannot be fired through by commercial Aluminum screen printed paste, while there exists a least-damage, fast technique to locally remove such layer prior to metallization, and that (c) does not interact with the capping metal layer during the firing process or when local contacts are otherwise formed through it.

Due to its characteristics this process
provides an efficient surface passivation, where
it is possible to make local (BSF) contacts, and
the process eliminates the bowing problems when using ultra-thin wafers or substrates (e.g. problems when combined with Al screen printed paste on ultra-thin wafers).

A generic low quality amorphous oxide was deposited (e.g. SiO2, SiOx, SOG, TiO2, Al2O3 . . . or their pseudo-alloys, SiONx,) on the solar cell's rear side silicon surface (e.g. by APCVD, or spin coating). The surface passivation properties of the dielectric layer were improved by depositing an optimized hydrogenated dielectric layer (namely: SiNx:H). Such stacks retain the passivation properties during short high temperature treatments. The passivation properties are even improved during this treatment. This feature is important as it enables the use of the contact co-firing process that takes place in most of the industrial silicon solar cells' process sequence. Moreover, given that a) it is resistant to firing; i.e. it doesn't lose its relevant characteristics, b) it cannot be fired through, but c) it is possible to create local openings or holes in it by techniques such as e.g. etching paste or laser ablation, this embodiment enables for an easy way to create Local Back Surface Field (LBSF) contacts by selective alloying, during the firing process itself. The alloying process partially recovers any surface damage that may have incurred during the opening of the layer, thereby further simplifying the process. During the alloying, part of the Si surface and subsurface forms an alloy with the metal. The surface termination is therefore not crucial, as it would be e.g. when depositing another semiconductor, or a dielectric. A back surface field is formed and the effect of residual subsurface damage will be reduced, to a certain extent.

In an example, illustrated in FIG. 1, pyrolithic silicon oxide (Pyrox) 1 was deposited by atmospheric pressure chemical vapor deposition (APCVD) onto a silicon substrate 2. As opposed to conventional thermal oxides, or wet oxides, which are known to be excellent for surface passivation of silicon, pyrox has poor passivation properties and finds its application in microelectronics as an inexpensive and convenient diffusion mask, or dopant source. In fact, it can be deposited at about 400° C., which means that even low quality silicon material can withstand the deposition process without risk of thermal poisoning.

Thermal annealing can, to some extent, improve the surface passivation quality of pyrox. However, prolonged treatments lead to a degradation of the sample.

Moreover, it has been observed that there may be a degradation of the surface passivation qualities with air exposure.

Hydrogenated silicon nitride (SiNx:H) 3 can be used to stably improve the quality of the pyrox/silicon interface 4. It is known that silicon nitride can lead to excellent surface and bulk passivation properties on silicon, reason for which it is widely used in solar cell technology. However, its application for rear side passivation of an industrial solar cell is not straightforward. There exists an interaction between silicon nitride and metal capping layer (i.e. the rear surface contact of the solar cell), that leads to decreased surface passivation and cell efficiency (it is believed that this interaction is more than a “shunt” effect as described e.g. in Dauwe S., Mittelstädt L., Metz A., Hezel R., “Experimental evidence of parasitic shunting in silicon nitride rear surface passivated solar cells”, Prog. Photovolt. Res. Appl., 10 (4), 271-278, (2002)). Also the nitride recipes which are known to be best at surface passivation cannot withstand high temperature treatments such as the one that takes place during cofiring of the contacts. On the other hand, it is known that hydrogenated silicon nitride can release hydrogen during high temperature annealing treatments.

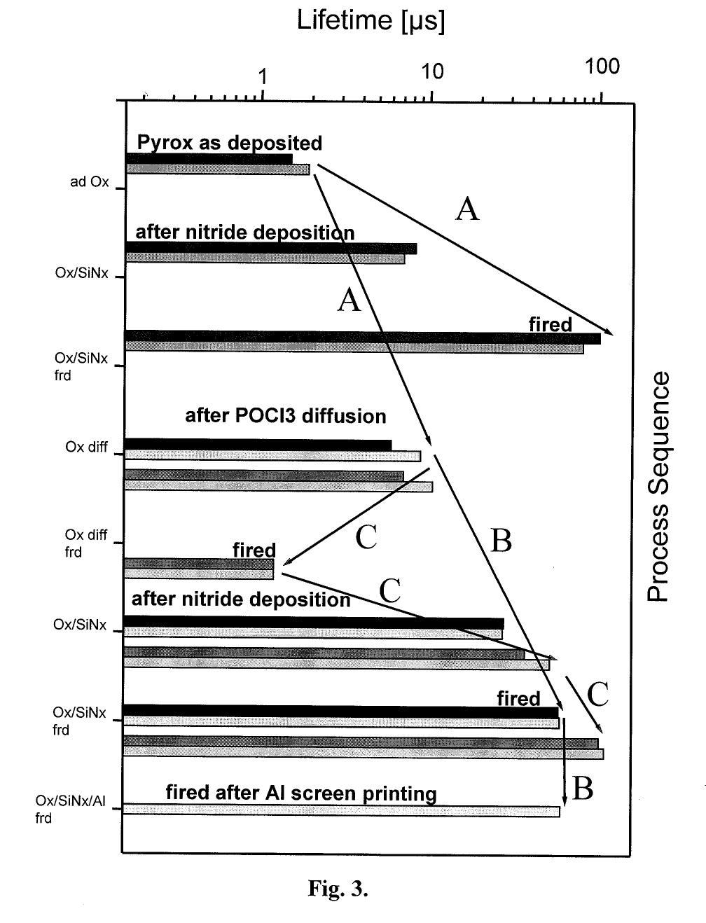

It is believed that the silicon nitride is used as a hydrogen source for the low quality oxide underneath, thereby significantly improving its surface passivation properties. In FIG. 3, the trends observed in the effective lifetimes in Cz wafers after different passivation and thermal treatments are shown. Assuming that the bulk lifetime is essentially constant, the effective lifetimes give a direct indication of the quality of surface passivation. The pyrox layer in this experiment was 800 nm thick, excluding any field-induced passivation effect from the overlying silicon nitride, which is in the prior art believed to be the reason for the good passivation quality.

Right after the deposition, the surface passivation quality of the pyrox is very poor. After nitride deposition on top of the pyrox layer there is a limited improvement (path A) and finally when firing the samples, an excellent surface passivation is achieved. Thermal cycles, like e.g. the ones that takes place with POCl3 diffusion (see FIG. 3), lead to a limited surface passivation improvement like the one observed after nitride deposition, before firing. Nitride deposition on top of the pyrox and firing, once again, lead to excellent surface passivation (path B). Firing with or without a metal layer on top lead to the same good results (see the example after Al screen printing in FIG. 3). It has been shown that firing alone (without the SiN layer deposition process first) is not beneficial. If firing is applied to the pyrox layer alone, there is a degradation of its surface passivation properties. Nonetheless, these can be recovered by subsequent nitride deposition and firing (path C).

A further advantage of the technique is that since it can be applied to low quality oxides, it can be applied directly on diffusion mask oxides too, greatly simplifying the solar cell process.

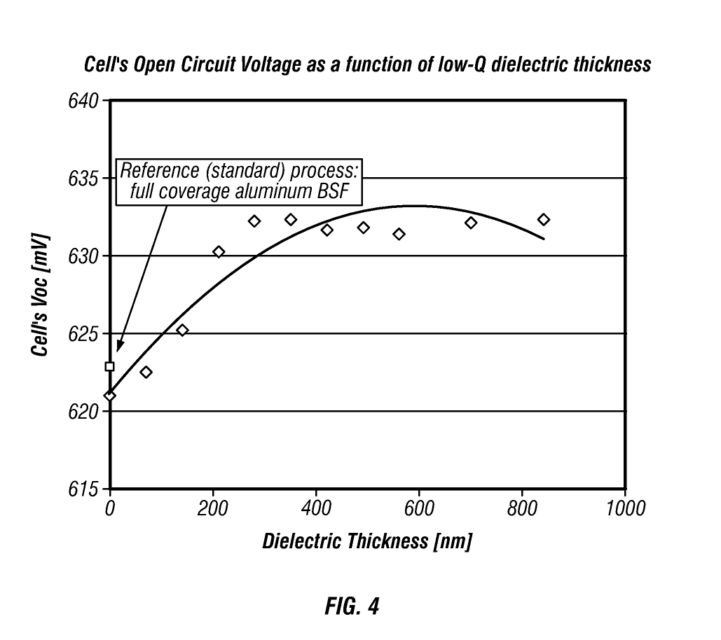

Dielectric layer stacks with a dielectric layer with thickness between 100 nm and 1500 nm have been deposited. When implemented in solar cells, the open circuit voltage has been measured as a function of the low quality dielectric thickness, as illustrated in FIG. 4 in particular for oxide. It can be seen from the graph in FIG. 4 that dielectric thicknesses approximately between 100 nm and 800 nm provide improved open circuit voltages with respect to the open circuit voltage of a cell obtained by a standard prior art process of full coverage aluminum BSF.

Other stacks than the above-mentioned silicon (substrate)/low quality oxide (dielectric layer)/silicon nitride (passivation layer) stack can for example be
silicon (substrate)/dielectric or wide bandgap (>2 eV, preferably >3 eV) semiconductor, such as e.g. silicon carbide (SiC), aluminum nitride (AlN), gallium nitride (GaN) or boron nitride (BN)/silicon nitride
silicon (substrate)/silicon nitride/low quality oxide
silicon (substrate)/silicon nitride/wide bandgap (>2 eV, preferably >3 eV) semiconductor or dielectric
silicon (substrate)/Al2O3/low quality oxide
silicon (substrate)/Al2O3/wide bandgap (>2 eV, preferably >3 eV) semiconductor or dielectric

In each of the above stacks, the dielectric layer stack has a thickness above about 100 nm.

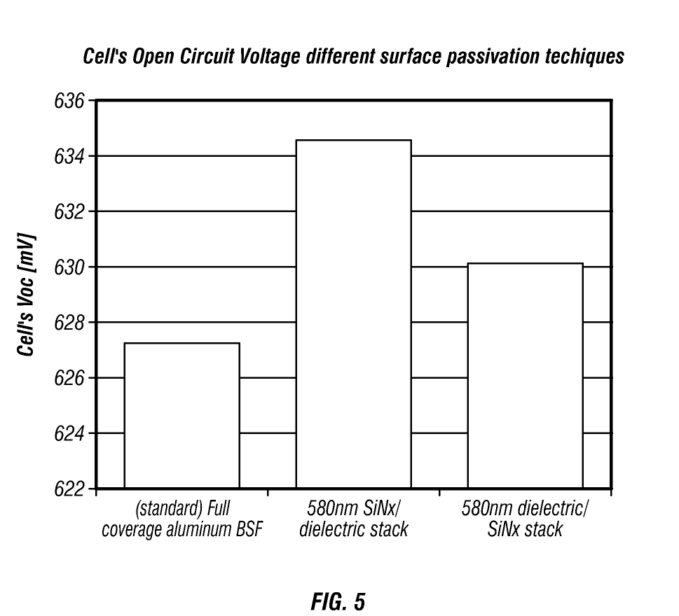

FIG. 5 illustrates the open circuit voltage of three cells with different rear surface passivation schemes: the standard full coverage screen printed aluminum BSF used in crystalline silicon solar cell production (left); a SiNx/dielectric stack, with dielectric on the silicon substrate, the dielectric stack having a thickness of approximately 580 nm (middle); and a dielectric/SiNx stack with SiNx on the silicon substrate, the dielectric stack also having a thickness of approximately 580 nm (right). It can be seen that both thick dielectric layer stacks according to one embodiment, i.e. the dielectric layer stacks having a thickness of at least about 200 nm, preferably at least 250 nm, provide better results with respect to open circuit voltage than the standard full coverage aluminum BSF.

### Examples of Process Sequences

A typical process sequence for surface passivation can comprise:
Chemical cleaning
Low quality oxide deposition (about 100 to 1500 nm)
Silicon nitride deposition; for instance Low Frequency (450 kHz) direct PECVD Hydrogenated SiNx deposited at 400 degrees from SiH4 and NH3 precursors
Firing in a three-zone belt furnace, at high belt speed (e.g. more than 100 inch/min), peak set temperature of the furnace up to 960° C.

This method for surface passivation can be integrated in the process sequence of a solar cell, in different situations:

A) Deposition after Diffusion
Front side texturing
Diffusion, e.g. P diffusion, resulting in doped, e.g. P-doped, regions all around the substrate, i.e. both at the front surface and the rear surface
Glass removal, e.g. P-glass removal,
Etching of Si at the rear (sufficient to remove P-doped region at rear)
Chemical cleaning
Low quality oxide deposition
Silicon nitride deposition (rear and possibly front)
Forming of back contacts, e.g. by
   Opening of the local contacts (e.g. by etching paste, scribing or laser ablation)
   Metal deposition (e.g. evaporation, sputtering, screen printing)
   Firing in a commercial belt furnace

### B) Before Diffusion

Chemical cleaning
Low quality oxide deposition
Diffusion (will only take place at the front surface to form the emitter, as at the rear surface low-quality oxide has been deposited and functions as a mask for the diffusion)
Silicon nitride deposition (rear and possibly front side)
Forming of back contacts, e.g. by
   Opening of local contacts (e.g. by etching paste, scribing or laser ablation)
   Metal deposition (e.g. evaporation, sputtering, screen printing)
   Firing in a belt furnace

The foregoing description details certain embodiments of the invention. It will be appreciated, however, that no matter how detailed the foregoing appears in text, the invention may be practiced in many ways. It should be noted that the use of particular terminology when describing certain features or aspects of the invention should not be taken to imply that the terminology is being re-defined herein to be restricted to including any specific characteristics of the features or aspects of the invention with which that terminology is associated.

While the above detailed description has shown, described, and pointed out novel features of the invention as applied to various embodiments, it will be understood that various omissions, substitutions, and changes in the form and details of the device or process illustrated may be made by those skilled in the technology without departing from the spirit of the invention. The scope of the invention is indicated by the appended claims rather than by the foregoing description. All changes which come within the meaning and range of equivalency of the claims are to be embraced within their scope.

What is claimed is:

1. A method of producing a photovoltaic device comprising:
i. providing a semiconductor substrate having a front main surface for collecting impinging light and a rear surface opposite to the front main surface;
ii. depositing a dielectric layer or a wide bandgap semiconductor layer on the rear surface, the dielectric layer having a thickness larger than about 100 nm;
iii. depositing a passivation layer comprising hydrogenated SiN on top of the dielectric layer or the wide bandgap semiconductor layer; and
iv. forming back contacts through the dielectric layer or wide bandgap semiconductor layer and the passivation layer.

2. A method of producing a photovoltaic device comprising:
i. providing a semiconductor substrate having a front main surface for collecting impinging light and a rear surface opposite to the front main surface;
ii. depositing a dielectric layer stack on the rear surface, wherein the dielectric layer stack comprises a sub-stack of dielectric layers and/or wide bandgap semiconductor layers, the sub-stack having a thickness larger than about 100 nm, the dielectric layer stack having a thickness larger than about 200 nm; and
iii. forming back contacts through the dielectric layer stack.

3. The method according to claim 2, wherein depositing a dielectric layer stack on the rear surface comprises:
depositing the sub-stack of dielectric layers and/or wide bandgap semiconductor layers on the rear surface; and
depositing a passivation layer on top of the sub-stack.

4. The method according to claim 2, further comprising forming a high quality layer or an aluminium oxide layer in between the substrate and the sub-stack of dielectric layers and/or wide bandgap semiconductor layers.

5. The method according to claim 2, wherein the thickness of the sub-stack of dielectric layers and/or wide bandgap semiconductor layers is approximately between 100 nm and 1500 nm, preferably between 150 nm and 1200 nm, more preferably between 200 nm and 1200 nm, still more preferably between 400 nm and 800 nm or between 800 nm and 1200 nm.

6. The method according to claim 2, wherein depositing a sub-stack of dielectric layers and/or wide bandgap semiconductor layers comprises depositing one or more low quality dielectric layers or SiN layers.

7. The method according to claim 6, wherein depositing a low quality dielectric layer comprises depositing a low quality oxide or a low quality amorphous oxide.

8. The method according to claim 7, wherein the low-quality amorphous oxide is APCVD pyrolithic oxide, spin-on oxide, spray-on oxide or dip oxide.

9. The method according to claim 2, wherein forming back contacts comprises:
forming holes in the dielectric layer stack; and
depositing a layer of contacting material onto the dielectric layer stack, hereby filling the holes.

10. The method according to claim 9, wherein the layer of contacting material is discontinuous.

11. The method according to claim 10, wherein after the depositing of the layer of contacting material, the contacting material is deposited essentially in the holes.

12. The method according to claim 9, wherein depositing a layer of contacting material is performed by evaporation, sputtering or screen printing.

13. The method according to claim 9, wherein the forming of holes is performed by applying an etching paste, by scribing or by laser ablation.

14. The method according to claim 9, further comprising applying a high temperature process at a temperature approximately between 600 and 1000 degrees Celsius to the layer of contacting material.

15. The method according to claim 14, wherein the high temperature process is a contact firing process performed at a temperature approximately higher than 730 degrees Celsius and below 960 degrees Celsius.

16. The method according to claim 2, further comprising performing diffusion and emitter removal prior to the depositing of the dielectric layer stack.

17. The method according to claim 2, further comprising performing diffusion after the depositing of a sub-stack of a dielectric layer or a wide bandgap semiconductor layer and before the depositing of a passivation layer.

18. The method according to claim 17, wherein the sub-stack of a dielectric layer or wide bandgap semiconductor layer is used as a diffusion mask.

19. The method according to claim 2, wherein the front main surface has undergone a typical solar cell front surface processing.

20. The method according to claim 2, wherein the substrate is thinner than about 250 micron, or thinner than about 200 or thinner than about 150 micron.

21. The method according to claim 2 wherein the substrate is thinner than about 250 micron, or thinner than about 200 or thinner than about 150 micron.

22. A photovoltaic device obtainable by a process comprising the method according to claim 2.

23. A photovoltaic device comprising
i. a semiconductor substrate having a front main surface for collecting impinging light and a rear surface opposite to the front main surface,
ii. a dielectric layer or a wide bandgap semiconductor layer on the rear surface, the dielectric layer or wide bandgap semiconductor layer having a thickness larger than 100 nm,
iii. a passivation layer comprising hydrogenated SiN on top of the dielectric layer or wide bandgap semiconductor layer, and
iv. back contacts through the dielectric layer or wide bandgap semiconductor layer and the hydrogenated SiN.

24. A photovoltaic device comprising
i. a semiconductor substrate having a front main surface for collecting impinging light and a rear surface opposite to the front main surface,
ii. a dielectric layer stack on the rear surface, wherein the dielectric layer stack comprises a sub-stack of dielectric layers and/or wide bandgap semiconductor layers, the sub-stack having a thickness larger than 100 nm, the dielectric layer stack having a thickness larger than 200 nm, and
iii. back contacts through the dielectric layer stack.
